(19) United States
(12) Patent Application Publication
(10) Pub. No.: US 2013/0335808 A1
(43) Pub. Date: Dec. 19, 2013

(54) ANALOG IMOD HAVING HIGH FILL FACTOR

(71) Applicant: Teruo Sasagawa, Los Gatos, CA (US)

(72) Inventor: Teruo Sasagawa, Los Gatos, CA (US)

(73) Assignee: QUALCOMM MEMS TECHNOLOGIES, INC., San Diego, CA (US)

(21) Appl. No.: 13/523,165

(22) Filed: Jun. 14, 2012

(51) Int. Cl. G02B 26/00; H05K 3/30

(52) U.S. Cl. 359/295; 29/832

(57) ABSTRACT

This disclosure provides systems, methods and apparatus related to an electromechanical display device. In one aspect, an analog interferometric modulator (AIMOD) includes a reflective display pixel having a movable element disposed between first and second electrodes. The movable element includes a third electrode embedded within a deformable layer and a reflector. The movable element is moved to different positions between first and second electrodes, with different positions corresponding to different reflected colors from the AIMOD. In another aspect, the reflector is coupled to, but spaced apart from, the deformable layer, thereby decoupling the mechanical and optical properties of the movable element. In another aspect, the need for a bending region in the reflector is eliminated, providing for increased fill factor. In another aspect, the reflector may include a dielectric layer having substantially identical metal layers above and below, so as to provide increased rigidity to the reflector.

### TECHNICAL FIELD

This disclosure relates to electromechanical systems and display devices for actively displaying images.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulators include bi-stable devices which are configured to place a pair of at least partially reflective plates at two positions relative to each other (an actuated position and a relaxed position), and analog interferometric modulators (AIMODS) which are configured to place the pair of plates at more than two different positions relative to each other, each position causing the device to have a different light absorption and/or reflection characteristics. Interferometric modulator devices have a wide range of applications, and can be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in an analog interferometric modulator (AIMOD) comprising a stationary first electrode disposed over a substrate, an optical stack disposed over the first electrode, a stationary second electrode disposed over the optical stack and spaced apart from the optical stack by a first gap, and a movable element disposed between the optical stack and second electrode. The movable element can have a third electrode and be configured to move in response to at least one of a first electric field between the first and third electrodes and a second electric field between the second and third electrodes to at least three different positions relative to the optical stack, each position corresponding to a different color reflected from the AIMOD. The movable element can further include a reflector having a first metal layer disposed facing the optical stack, and a first dielectric layer disposed such that the first metal layer is between the first dielectric layer and the optical stack. The movable element can further include a deformable layer coupled to a portion of the reflector, the deformable layer disposed such that the reflector is between the deformable layer and the optical stack, wherein a portion of the deformable layer is spaced apart from a portion of the reflector by a second gap.

In some implementations, the first metal layer can include aluminum. In some implementations, the first metal layer can have a thickness of at least about 300 Å. In some implementations, the first dielectric layer can include nitrous oxide. In some implementations, the first dielectric layer has a thickness of at least about 5000 Å. In some implementations, the first metal layer can have a reflective surface that is disposed substantially parallel to the optical stack. In some implementations, the first metal layer can be disposed over a second dielectric layer. In some implementations, a second metal layer can be disposed over the first dielectric layer. In some implementations, the first and second metal layers can be electrically connected and form part of the third electrode.

In some implementations, the reflector can further include a second dielectric layer disposed below the first metal layer, a third dielectric layer disposed over the second metal layer, a first optical layer disposed below the second dielectric layer, and a second optical layer disposed above the third dielectric layer. In some implementations, the second and third dielectric layers can each have a thickness of at least about 650 Å.

In some implementations, the deformable layer can include a third metal layer, a fourth dielectric layer disposed below the third metal layer, and a fifth dielectric layer disposed above the third metal layer. The fourth and fifth dielectric layers can each have a thickness of at least about 1000 Å. In some implementations, the third metal layer can be electrically connected to the first and second metal layers.

Another innovative aspect of the subject matter described in this disclosure can be implemented in an analog interferometric modulator (AIMOD) comprising stationary first means for conducting electrostatic charge disposed over a substrate, means for absorbing light disposed over the first conducting means, stationary second means for conducting electrostatic charge disposed over the absorbing means and spaced apart from the absorbing means by a first gap, and a movable element disposed between the absorbing means and the second conducting means. The movable element can have third means for conducting electrostatic charge and being configured to move in response to at least one of a first electric field between the first and third conducting means and a second electric field between the second and third conducting means to at least three different positions relative to the absorbing means, each position corresponding to a different color reflected from the AIMOD. The movable element can further include means for reflecting light, the reflecting means including a first metal layer disposed facing the absorbing means, and a first dielectric layer disposed such that the first metal layer is between the first dielectric layer and the absorbing means. The movable element can further include a deformable layer coupled to a portion of the reflecting means, the deformable layer disposed such that the reflecting means is between the deformable layer and the absorbing means, wherein a portion of the deformable layer is spaced apart from a portion of the reflecting means by a second gap. In some implementations, the first conducting means includes a first electrode. In some implementations, the absorbing means includes an optical stack. In some implementations, the second conducting means includes a second electrode. In some implementations, the third conducting means includes a third electrode. In some implementations, the reflecting means includes a reflector.

Another innovative aspect of the subject matter described in this disclosure can be implemented in an a method of manufacturing an analog interferometric modulator (AIMOD), the method comprising disposing a stationary first electrode over a substrate, disposing an optical stack over the first electrode, disposing a first sacrificial layer over the optical stack, disposing a movable element over the first sacrificial layer, disposing a second sacrificial layer over the movable element, disposing a second stationary electrode over the second sacrificial layer, removing the first sacrificial layer to create a first gap between the optical stack and the movable element, and removing the second sacrificial layer to create a second gap between the movable element and the second electrode. The movable element can have a third electrode and be configured to move in response to at least one of a first electric field between the first and third electrodes and a second electric field between the second and third electrodes to at least three different positions relative to the optical stack, each position corresponding to a different color reflected from the AIMOD. The movable element can include a reflector having a first metal layer disposed facing the optical stack, and a first dielectric layer disposed such that the first metal layer is between the first dielectric layer and the optical stack. The movable element can further include a deformable layer coupled to a portion of the reflector, the deformable layer disposed such that the reflector is between the deformable layer and the optical stack, and a portion of the deformable layer can be spaced apart from a portion of the reflector by a second gap.

In some implementations, a second dielectric layer can be disposed over the first metal layer, and a second metal layer can be disposed over the second dielectric layer. In some implementations, the first and second metal layers can be electrically connected and form part of the third electrode. In some implementations, the first metal layer can have a thickness of at least about 300 Å. In some implementations, the first dielectric layer can have a thickness of at least about 5000 Å.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 shows an example of an isometric view depicting two adjacent pixels in a series of pixels of an interferometric modulator (IMOD) display device.

FIG. 2 shows an example of a system block diagram illustrating an electronic device incorporating a 3×3 interferometric modulator display.

FIG. 3 shows an example of a diagram illustrating movable reflective layer position versus applied voltage for the interferometric modulator of FIG. 1.

FIG. 4 shows an example of a table illustrating various states of an interferometric modulator when various common and segment voltages are applied.

FIG. 5A shows an example of a diagram illustrating a frame of display data in the 3×3 interferometric modulator display of FIG. 2.

FIG. 5B shows an example of a timing diagram for common and segment signals that may be used to write the frame of display data illustrated in FIG. 5A.

FIG. 6A shows an example of a partial cross-section of the interferometric modulator display of FIG. 1.

FIGS. 6B-6E show examples of cross-sections of varying implementations of interferometric modulators.

FIG. 7 shows an example of a flow diagram illustrating a manufacturing process for an interferometric modulator.

FIGS. 8A-8E show examples of cross-sectional schematic illustrations of various stages in a method of making an interferometric modulator.

FIGS. 9A and 9B show examples of a cross-section of an analog interferometric modulator (AIMOD).

FIG. 10A shows another example of a cross-section of an AIMOD.

FIG. 10B shows an enlarged detail view of the movable element shown in FIG. 10A.

FIGS. 11A-G show examples of cross-sectional schematic illustrations of various stages in one implementation of a method of making an AIMOD.

FIG. 12 shows an example of a flow diagram illustrating one implementation of a method of manufacturing an AIMOD.

FIGS. 13A and 13B show examples of system block diagrams illustrating a display device that includes a plurality of interferometric modulators.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, Bluetooth® devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

The fill factor of an analog interferometric modulator (AIMOD) may be defined as the ratio of the optically active area of the device relative to the total area. AIMODs may suffer from reduced fill factor due to bending regions near the perimeter of the reflector. In some AIMODS, the movable element includes a reflector attached directly to a mechanical layer, spaced apart from a substrate by support posts. When actuated, the movable element (including both the reflector and the mechanical layer) bends in the regions near the support posts. Due to this movement, the optical properties of the reflector are distorted in the bending region. Accordingly, to improve image quality, in some AIMODS the bending region may be covered with a black mask, which can result in the AIMOD reflecting a more saturated color. The region not covered by the black mask is generally referred to as the optically active area. The fill factor of an AIMOD may be defined as the ratio of the optically active area of the device relative to the total area of the device. The loss of optically active area at or near the bending regions causes reduction in fill factor in many AIMODs. Improved fill factor in AIMODs can be achieved by utilizing a movable element having a separate reflector and deformable layer. The movable element can be configured such that the deformable layer bends during actuation, but the reflector does not. As the loss of active region due to bending in the reflector is reduced or eliminated, the fill factor of the AIMOD can be improved. In some implementations, the reflector may be configured to include a dielectric layer having identical metal layers above and below the dielectric layer. Such symmetrical structure helps to prevent mechanical bending due to differences in the coefficients of thermal expansion (CTE) between the layers.

Particular implementations of the subject matter described in this disclosure can be implemented to realize one or more of the following potential advantages. In some implementations, an AIMOD array can include improved fill factor by reducing the loss associated with the bending regions. Additionally, some implementations can decrease the number of manufacturing steps required to manufacture an AIMOD. Furthermore, some implementations can improve the reflective properties of the reflector in AIMODs.

An example of a suitable MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

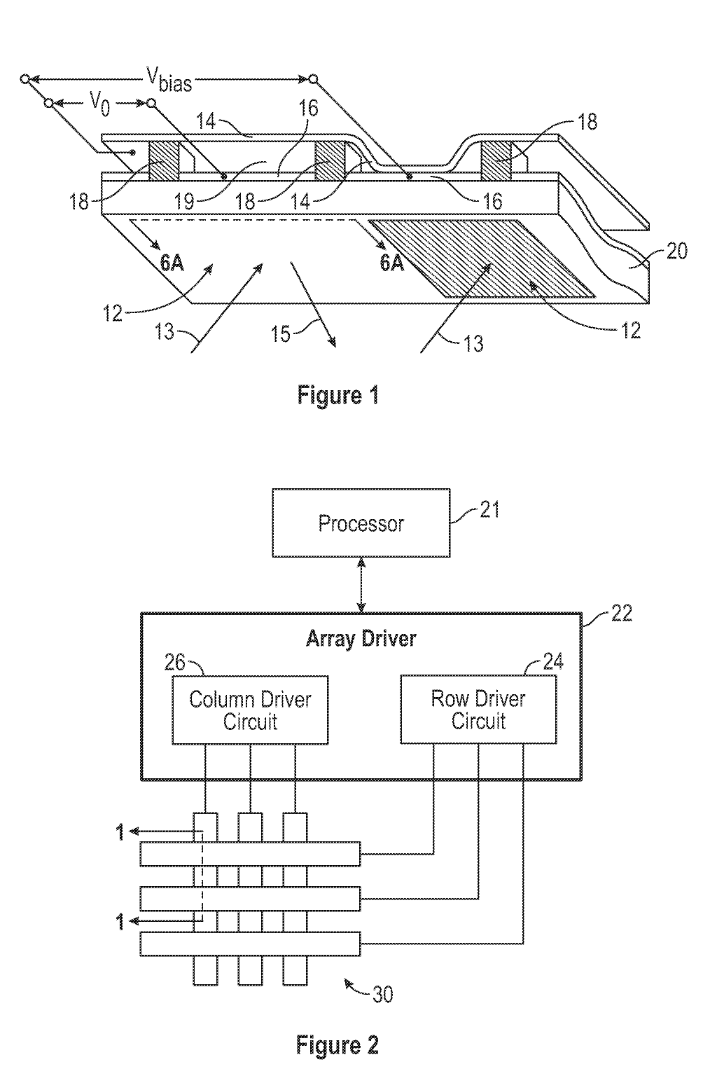

FIG. 1 shows an example of an isometric view depicting two adjacent pixels in a series of pixels of an interferometric modulator (IMOD) display device. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off') state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when actuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted portion of the pixel array in FIG. 1 includes two adjacent interferometric modulators 12. In the IMOD 12 on the left (as illustrated), a movable reflective layer 14 is illustrated in a relaxed position at a predetermined distance from an optical stack 16, which includes a partially reflective layer. The voltage V₀ applied across the IMOD 12 on the left is insufficient to cause actuation of the movable reflective layer 14. In the IMOD 12 on the right, the movable reflective layer 14 is illustrated in an actuated position near or adjacent the optical stack 16. The voltage V_{bias} applied across the IMOD 12 on the right is sufficient to maintain the movable reflective layer 14 in the actuated position.

In FIG. 1, the reflective properties of pixels 12 are generally illustrated with arrows indicating light 13 incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixel 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the layer(s) of the optical stack 16 can be patterned into parallel strips, and may form row electrodes in a display device as described further below. As will be understood by one having skill in the art, the term “patterned” is used herein to refer to masking as well as etching processes. In some implementations, a highly conductive and reflective material, such as aluminum (Al), may be used for the movable reflective layer 14, and these strips may form column electrodes in a display device. The movable reflective layer 14 may be formed as a series of parallel strips of a deposited metal layer or layers (orthogonal to the row electrodes of the optical stack 16) to form columns deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 on the left in FIG. 1, with the gap 19 between the movable reflective layer 14 and optical stack 16. However, when a potential difference, e.g., voltage, is applied to at least one of a selected row and column, the capacitor formed at the intersection of the row and column electrodes at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 on the right in FIG. 1. The behavior is the same regardless of the polarity of the applied potential difference. Though a series of pixels in an array may be referred to in some instances as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

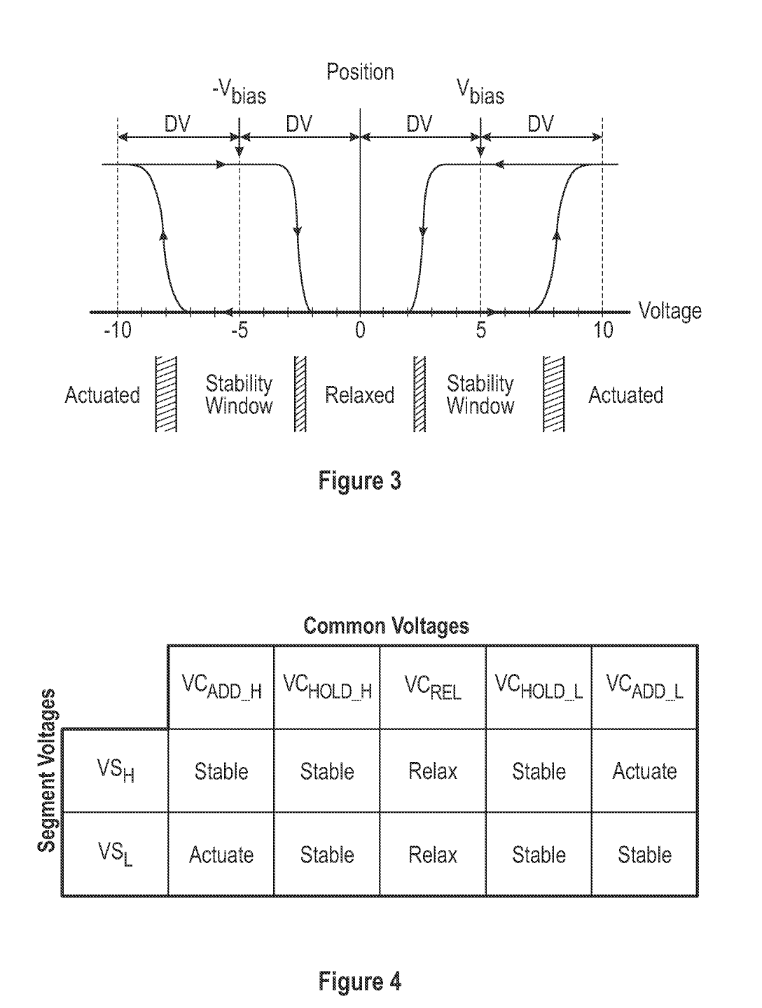

FIG. 2 shows an example of a system block diagram illustrating an electronic device incorporating a 3×3 interferometric modulator display. The electronic device includes a processor 21 that may be configured to execute one or more software modules. In addition to executing an operating system, the processor 21 may be configured to execute one or more software applications, including a web browser, a telephone application, an email program, or any other software application.

The processor 21 can be configured to communicate with an array driver 22. The array driver 22 can include a row driver circuit 24 and a column driver circuit 26 that provide signals to, e.g., a display array or panel 30. The cross section of the IMOD display device illustrated in FIG. 1 is shown by the lines 1-1 in FIG. 2. Although FIG. 2 illustrates a 3×3 array of IMODs for the sake of clarity, the display array 30 may contain a very large number of IMODs, and may have a different number of IMODs in rows than in columns, and vice versa.

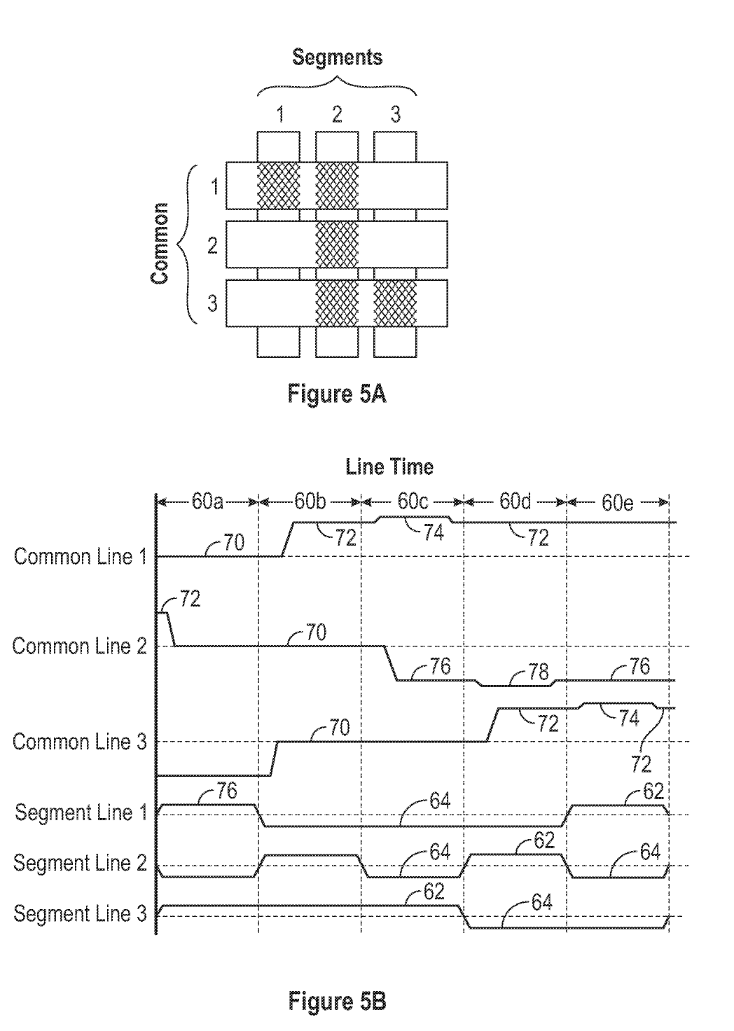

FIG. 3 shows an example of a diagram illustrating movable reflective layer position versus applied voltage for the interferometric modulator of FIG. 1. For MEMS interferometric modulators, the row/column (i.e., common/segment) write procedure may take advantage of a hysteresis property of these devices as illustrated in FIG. 3. An interferometric modulator may require, for example, about a 10-volt potential difference to cause the movable reflective layer, or mirror, to change from the relaxed state to the actuated state. When the voltage is reduced from that value, the movable reflective layer maintains its state as the voltage drops back below, e.g., 10-volts, however, the movable reflective layer does not relax completely until the voltage drops below 2-volts. Thus, a range of voltage, approximately 3 to 7-volts, as shown in FIG. 3, exists where there is a window of applied voltage within which the device is stable in either the relaxed or actuated state. This is referred to herein as the “hysteresis window” or “stability window.” For a display array 30 having the hysteresis characteristics of FIG. 3, the row/column write procedure can be designed to address one or more rows at a time, such that during the addressing of a given row, pixels in the addressed row that are to be actuated are exposed to a voltage difference of about 10-volts, and pixels that are to be relaxed are exposed to a voltage difference of near zero volts. After addressing, the pixels are exposed to a steady state or bias voltage difference of approximately 5-volts such that they remain in the previous strobing state. In this example, after being addressed, each pixel sees a potential difference within the “stability window” of about 3-7-volts. This hysteresis property feature enables the pixel design, e.g., illustrated in FIG. 1, to remain stable in either an actuated or relaxed pre-existing state under the same applied voltage conditions. Since each IMOD pixel, whether in the actuated or relaxed state, is essentially a capacitor formed by the fixed and moving reflective layers, this stable state can be held at a steady voltage within the hysteresis window without substantially consuming or losing power. Moreover, essentially little or no current flows into the IMOD pixel if the applied voltage potential remains substantially fixed.

In some implementations, a frame of an image may be created by applying data signals in the form of “segment” voltages along the set of column electrodes, in accordance with the desired change (if any) to the state of the pixels in a given row. Each row of the array can be addressed in turn, such that the frame is written one row at a time. To write the desired data to the pixels in a first row, segment voltages corresponding to the desired state of the pixels in the first row can be applied on the column electrodes, and a first row pulse in the form of a specific “common” voltage or signal can be applied to the first row electrode. The set of segment voltages can then be changed to correspond to the desired change (if any) to the state of the pixels in the second row, and a second common voltage can be applied to the second row electrode. In some implementations, the pixels in the first row are unaffected by the change in the segment voltages applied along the column electrodes, and remain in the state they were set to during the first common voltage row pulse. This process may be repeated for the entire series of rows, or alternatively, columns, in a sequential fashion to produce the image frame. The frames can be refreshed and/or updated with new image data by continually repeating this process at some desired number of frames per second.

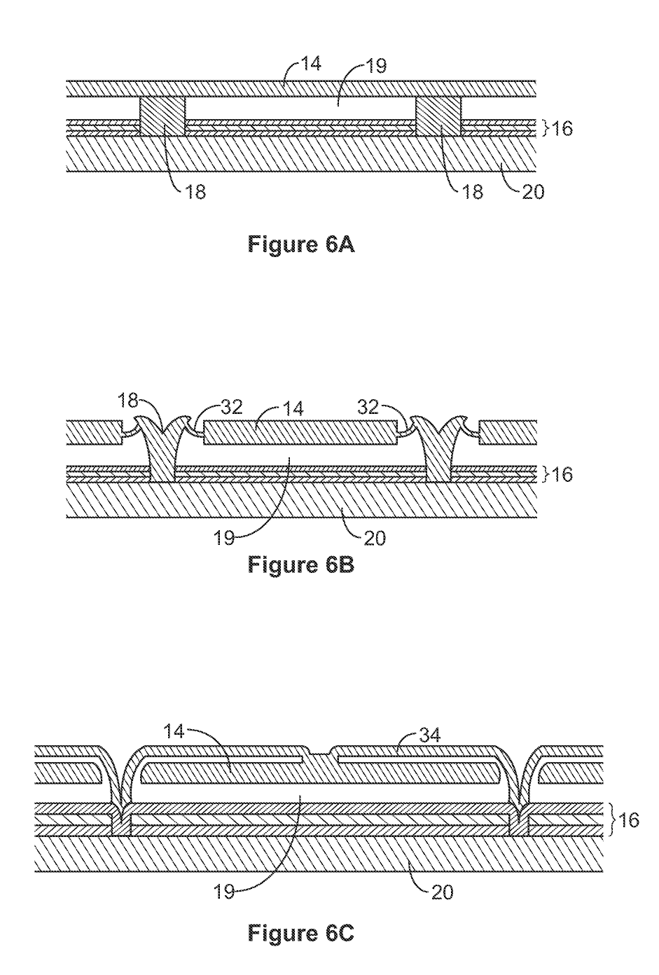

The combination of segment and common signals applied across each pixel (that is, the potential difference across each pixel) determines the resulting state of each pixel. FIG. 4 shows an example of a table illustrating various states of an interferometric modulator when various common and segment voltages are applied. As will be readily understood by one having ordinary skill in the art, the “segment” voltages can be applied to either the column electrodes or the row electrodes, and the “common” voltages can be applied to the other of the column electrodes or the row electrodes.

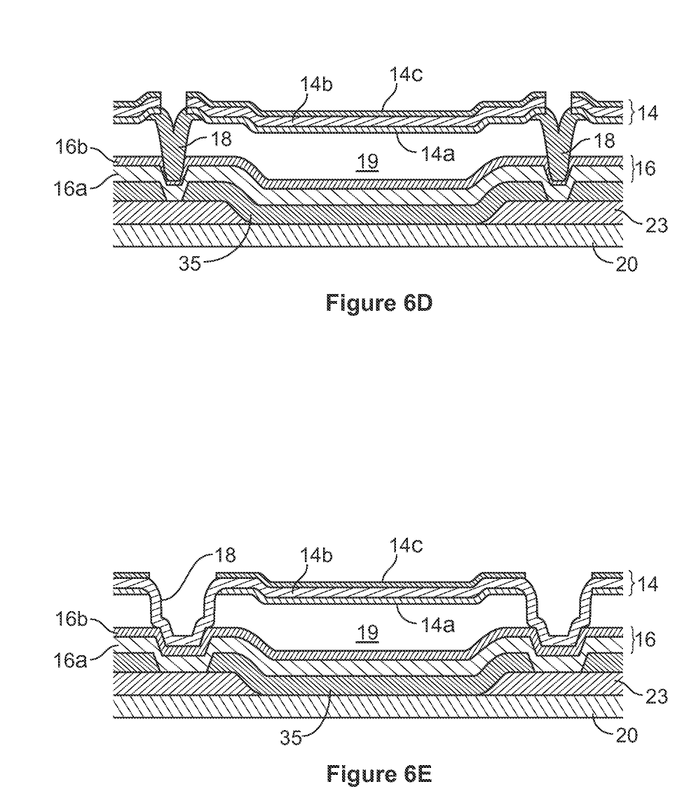

As illustrated in FIG. 4 (as well as in the timing diagram shown in FIG. 5B), when a release voltage VC_{REL} is applied along a common line, all interferometric modulator elements along the common line will be placed in a relaxed state, alternatively referred to as a released or unactuated state, regardless of the voltage applied along the segment lines, i.e., high segment voltage VS_{H} and low segment voltage VS_{L}. In particular, when the release voltage VC_{REL} is applied along a common line, the potential voltage across the modulator (alternatively referred to as a pixel voltage) is within the relaxation window (see FIG. 3, also referred to as a release window) both when the high segment voltage VS_{H} and the low segment voltage VS_{L} are applied along the corresponding segment line for that pixel.

When a hold voltage is applied on a common line, such as a high hold voltage VC_{HOLD}_{_{—}}_{H} or a low hold voltage VC_{HOLD}_{_{—}}_{L}, the state of the interferometric modulator will remain constant. For example, a relaxed IMOD will remain in a relaxed position, and an actuated IMOD will remain in an actuated position. The hold voltages can be selected such that the pixel voltage will remain within a stability window both when the high segment voltage VS_{H} and the low segment voltage VS_{L} are applied along the corresponding segment line. Thus, the segment voltage swing, i.e., the difference between the high VS_{H} and low segment voltage VS_{L}, is less than the width of either the positive or the negative stability window.

When an addressing, or actuation, voltage is applied on a common line, such as a high addressing voltage VC_{ADD}_{_{—}}_{H} or a low addressing voltage VC_{ADD}_{_{—}}_{L}, data can be selectively written to the modulators along that line by application of segment voltages along the respective segment lines. The segment voltages may be selected such that actuation is dependent upon the segment voltage applied. When an addressing voltage is applied along a common line, application of one segment voltage will result in a pixel voltage within a stability window, causing the pixel to remain unactuated. In contrast, application of the other segment voltage will result in a pixel voltage beyond the stability window, resulting in actuation of the pixel. The particular segment voltage which causes actuation can vary depending upon which addressing voltage is used. In some implementations, when the high addressing voltage VC_{ADD}_{_{—}}_{H} is applied along the common line, application of the high segment voltage VS_{H} can cause a modulator to remain in its current position, while application of the low segment voltage VS_{L} can cause actuation of the modulator. As a corollary, the effect of the segment voltages can be the opposite when a low addressing voltage VC_{ADD}_{_{—}}_{L} is applied, with high segment voltage VS_{H} causing actuation of the modulator, and low segment voltage VS_{L} having no effect (i.e., remaining stable) on the state of the modulator.

In some implementations, hold voltages, address voltages, and segment voltages may be used which always produce the same polarity potential difference across the modulators. In some other implementations, signals can be used which alternate the polarity of the potential difference of the modulators. Alternation of the polarity across the modulators (that is, alternation of the polarity of write procedures) may reduce or inhibit charge accumulation which could occur after repeated write operations of a single polarity.

FIG. 5A shows an example of a diagram illustrating a frame of display data in the 3×3 interferometric modulator display of FIG. 2. FIG. 5B shows an example of a timing diagram for common and segment signals that may be used to write the frame of display data illustrated in FIG. 5A. The signals can be applied to the, e.g., 3×3 array of FIG. 2, which will ultimately result in the line time 60e display arrangement illustrated in FIG. 5A. The actuated modulators in FIG. 5A are in a dark-state, i.e., where a substantial portion of the reflected light is outside of the visible spectrum so as to result in a dark appearance to, e.g., a viewer. Prior to writing the frame illustrated in FIG. 5A, the pixels can be in any state, but the write procedure illustrated in the timing diagram of FIG. 5B presumes that each modulator has been released and resides in an unactuated state before the first line time 60a.

During the first line time 60a: a release voltage 70 is applied on common line 1; the voltage applied on common line 2 begins at a high hold voltage 72 and moves to a release voltage 70; and a low hold voltage 76 is applied along common line 3. Thus, the modulators (common 1, segment 1), (1,2) and (1,3) along common line 1 remain in a relaxed, or unactuated, state for the duration of the first line time 60a, the modulators (2,1), (2,2) and (2,3) along common line 2 will move to a relaxed state, and the modulators (3,1), (3,2) and (3,3) along common line 3 will remain in their previous state. With reference to FIG. 4, the segment voltages applied along segment lines 1, 2 and 3 will have no effect on the state of the interferometric modulators, as none of common lines 1, 2 or 3 are being exposed to voltage levels causing actuation during line time 60a (i.e., VC_{REL}—relax and VC_{HOLD}_{_{—}}_{L}—stable).

During the second line time 60b, the voltage on common line 1 moves to a high hold voltage 72, and all modulators along common line 1 remain in a relaxed state regardless of the segment voltage applied because no addressing, or actuation, voltage was applied on the common line 1. The modulators along common line 2 remain in a relaxed state due to the application of the release voltage 70, and the modulators (3,1), (3,2) and (3,3) along common line 3 will relax when the voltage along common line 3 moves to a release voltage 70.

During the third line time 60c, common line 1 is addressed by applying a high address voltage 74 on common line 1. Because a low segment voltage 64 is applied along segment lines 1 and 2 during the application of this address voltage, the pixel voltage across modulators (1,1) and (1,2) is greater than the high end of the positive stability window (i.e., the voltage differential exceeded a predefined threshold) of the modulators, and the modulators (1,1) and (1,2) are actuated. Conversely, because a high segment voltage 62 is applied along segment line 3, the pixel voltage across modulator (1,3) is less than that of modulators (1,1) and (1,2), and remains within the positive stability window of the modulator; modulator (1,3) thus remains relaxed. Also during line time 60c, the voltage along common line 2 decreases to a low hold voltage 76, and the voltage along common line 3 remains at a release voltage 70, leaving the modulators along common lines 2 and 3 in a relaxed position.

During the fourth line time 60d, the voltage on common line 1 returns to a high hold voltage 72, leaving the modulators along common line 1 in their respective addressed states. The voltage on common line 2 is decreased to a low address voltage 78. Because a high segment voltage 62 is applied along segment line 2, the pixel voltage across modulator (2,2) is below the lower end of the negative stability window of the modulator, causing the modulator (2,2) to actuate. Conversely, because a low segment voltage 64 is applied along segment lines 1 and 3, the modulators (2,1) and (2,3) remain in a relaxed position. The voltage on common line 3 increases to a high hold voltage 72, leaving the modulators along common line 3 in a relaxed state.

Finally, during the fifth line time 60e, the voltage on common line 1 remains at high hold voltage 72, and the voltage on common line 2 remains at a low hold voltage 76, leaving the modulators along common lines 1 and 2 in their respective addressed states. The voltage on common line 3 increases to a high address voltage 74 to address the modulators along common line 3. As a low segment voltage 64 is applied on segment lines 2 and 3, the modulators (3,2) and (3,3) actuate, while the high segment voltage 62 applied along segment line 1 causes modulator (3,1) to remain in a relaxed position. Thus, at the end of the fifth line time 60e, the 3×3 pixel array is in the state shown in FIG. 5A, and will remain in that state as long as the hold voltages are applied along the common lines, regardless of variations in the segment voltage which may occur when modulators along other common lines (not shown) are being addressed.

In the timing diagram of FIG. 5B, a given write procedure (i.e., line times 60a-60e) can include the use of either high hold and address voltages, or low hold and address voltages. Once the write procedure has been completed for a given common line (and the common voltage is set to the hold voltage having the same polarity as the actuation voltage), the pixel voltage remains within a given stability window, and does not pass through the relaxation window until a release voltage is applied on that common line. Furthermore, as each modulator is released as part of the write procedure prior to addressing the modulator, the actuation time of a modulator, rather than the release time, may determine the necessary line time. Specifically, in implementations in which the release time of a modulator is greater than the actuation time, the release voltage may be applied for longer than a single line time, as depicted in FIG. 5B. In some other implementations, voltages applied along common lines or segment lines may vary to account for variations in the actuation and release voltages of different modulators, such as modulators of different colors.

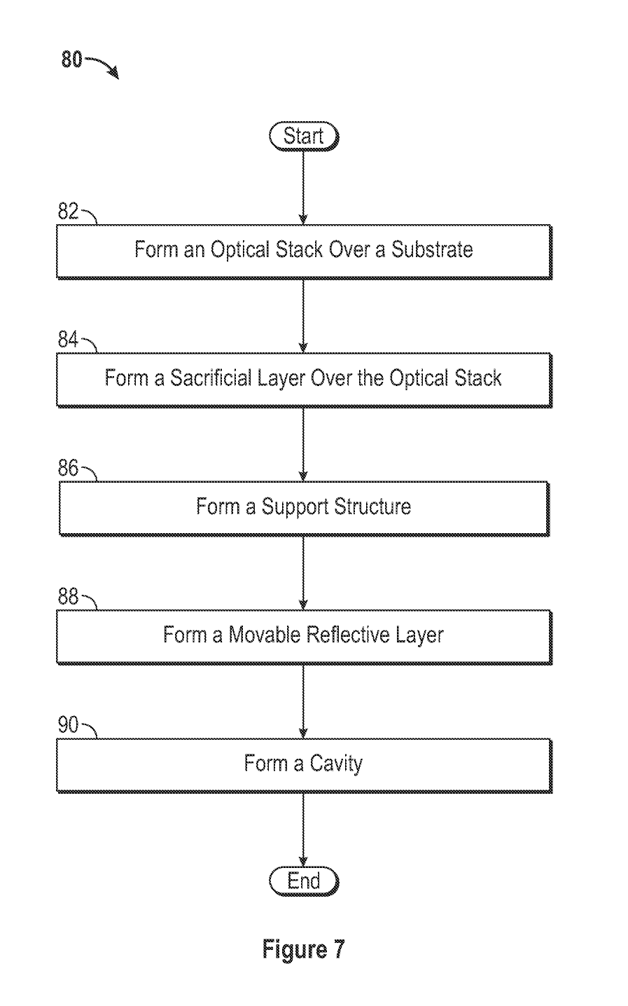

The details of the structure of interferometric modulators that operate in accordance with the principles set forth above may vary widely. For example, FIGS. 6A-6E show examples of cross-sections of varying implementations of interferometric modulators, including the movable reflective layer 14 and its supporting structures. FIG. 6A shows an example of a partial cross-section of the interferometric modulator display of FIG. 1, where a strip of metal material, i.e., the movable reflective layer 14 is deposited on supports 18 extending orthogonally from the substrate 20. In FIG. 6B, the movable reflective layer 14 of each IMOD is generally square or rectangular in shape and attached to supports at or near the corners, on tethers 32. In FIG. 6C, the movable reflective layer 14 is generally square or rectangular in shape and suspended from a deformable layer 34, which may include a flexible metal. The deformable layer 34 can connect, directly or indirectly, to the substrate 20 around the perimeter of the movable reflective layer 14. These connections are herein referred to as support posts. The implementation shown in FIG. 6C has additional benefits deriving from the decoupling of the optical functions of the movable reflective layer 14 from its mechanical functions, which are carried out by the deformable layer 34. This decoupling allows the structural design and materials used for the reflective layer 14 and those used for the deformable layer 34 to be optimized independently of one another.

FIG. 6D shows another example of an IMOD, where the movable reflective layer 14 includes a reflective sub-layer 1a. The movable reflective layer 14 rests on a support structure, such as support posts 18. The support posts 18 provide separation of the movable reflective layer 14 from the lower stationary electrode (i.e., part of the optical stack 16 in the illustrated IMOD) so that a gap 19 is formed between the movable reflective layer 14 and the optical stack 16, for example when the movable reflective layer 14 is in a relaxed position. The movable reflective layer 14 also can include a conductive layer 14c, which may be configured to serve as an electrode, and a support layer 14b. In this example, the conductive layer 14c is disposed on one side of the support layer 14b, distal from the substrate 20, and the reflective sub-layer 14a is disposed on the other side of the support layer 14b, proximal to the substrate 20. In some implementations, the reflective sub-layer 14a can be conductive and can be disposed between the support layer 14b and the optical stack 16. The support layer 14b can include one or more layers of a dielectric material, for example, silicon oxynitride (SiON) or silicon dioxide (SiO₂). In some implementations, the support layer 14b can be a stack of layers, such as, for example, a SiO₂/SiON/SiO₂ tri-layer stack. Either or both of the reflective sub-layer 14a and the conductive layer 14c can include, e.g., an aluminum (Al) alloy with about 0.5% copper (Cu), or another reflective metallic material. Employing conductive layers 14a, 14c above and below the dielectric support layer 14b can balance stresses and provide enhanced conduction. In some implementations, the reflective sub-layer 14a and the conductive layer 14c can be formed of different materials for a variety of design purposes, such as achieving specific stress profiles within the movable reflective layer 14.

As illustrated in FIG. 6D, some implementations also can include a black mask structure 23. The black mask structure 23 can be formed in optically inactive regions (e.g., between pixels or under posts 18) to absorb ambient or stray light. The black mask structure 23 also can improve the optical properties of a display device by inhibiting light from being reflected from or transmitted through inactive portions of the display, thereby increasing the contrast ratio. Additionally, the black mask structure 23 can be conductive and be configured to function as an electrical bussing layer. In some implementations, the row electrodes can be connected to the black mask structure 23 to reduce the resistance of the connected row electrode. The black mask structure 23 can be formed using a variety of methods, including deposition and patterning techniques. The black mask structure 23 can include one or more layers. For example, in some implementations, the black mask structure 23 includes a molybdenum-chromium (MoCr) layer that serves as an optical absorber, a layer, and an aluminum alloy that serves as a reflector and a bussing layer, with a thickness in the range of about 30-80 Å, 500-1000 Å, and 500-6000 Å, respectively. The one or more layers can be patterned using a variety of techniques, including photolithography and dry etching, including, for example, carbon tetrafluoride (CF₄) and/or oxygen (O₂) for the MoCr and SiO₂ layers and chlorine (Cl₂) and/or boron trichloride (BCl₃) for the aluminum alloy layer. In some implementations, the black mask 23 can be an etalon or interferometric stack structure. In such interferometric stack black mask structures 23, the conductive absorbers can be used to transmit or bus signals between lower, stationary electrodes in the optical stack 16 of each row or column. In some implementations, a spacer layer 35 can serve to generally electrically isolate the absorber layer 16a from the conductive layers in the black mask 23.

FIG. 6E shows another example of an IMOD, where the movable reflective layer 14 is self supporting. In contrast with FIG. 6D, the implementation of FIG. 6E does not include support posts 18. Instead, the movable reflective layer 14 contacts the underlying optical stack 16 at multiple locations, and the curvature of the movable reflective layer 14 provides sufficient support that the movable reflective layer 14 returns to the unactuated position of FIG. 6E when the voltage across the interferometric modulator is insufficient to cause actuation. The optical stack 16, which may contain a plurality of several different layers, is shown here for clarity including an optical absorber 16a, and a dielectric 16b. In some implementations, the optical absorber 16a may serve both as a fixed electrode and as a partially reflective layer.

In implementations such as those shown in FIGS. 6A-6E, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 6C) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing. Additionally, the implementations of FIGS. 6A-6E can simplify processing, such as, e.g., patterning.

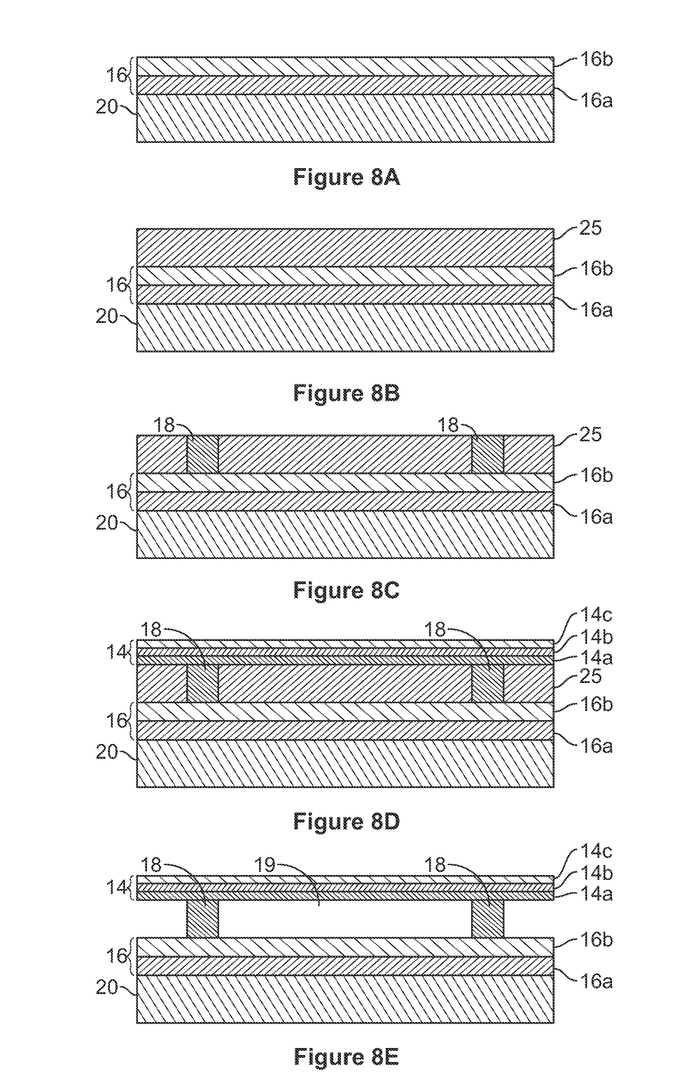

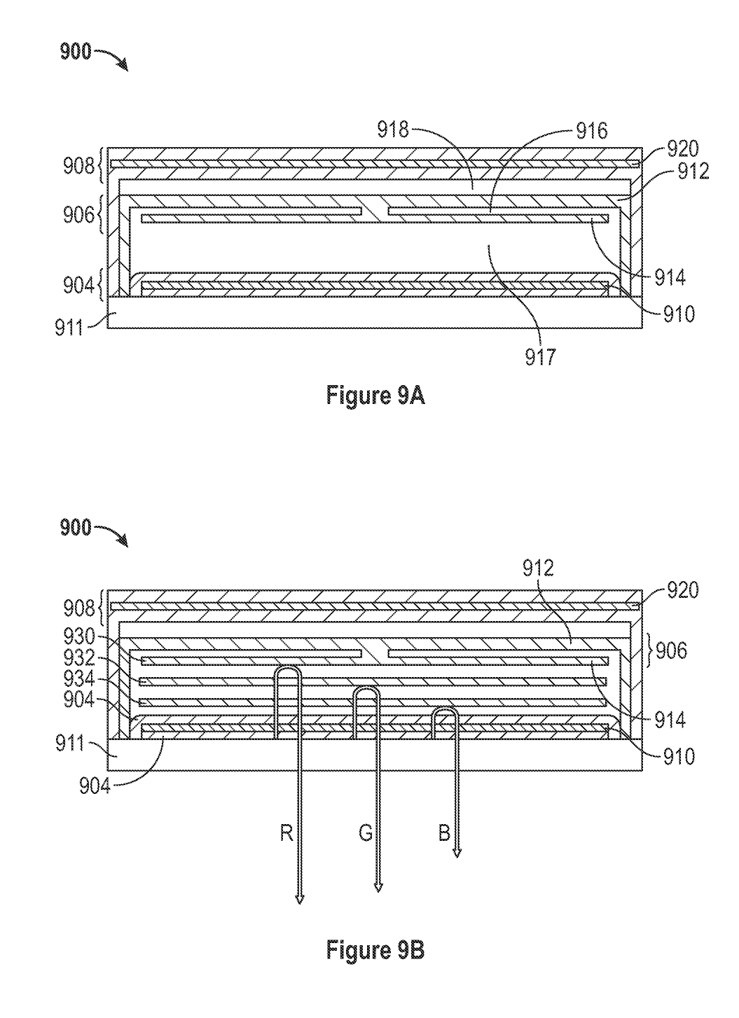

FIG. 7 shows an example of a flow diagram illustrating a manufacturing process 80 for an interferometric modulator, and FIGS. 8A-8E show examples of cross-sectional schematic illustrations of corresponding stages of such a manufacturing process 80. In some implementations, the manufacturing process 80 can be implemented to manufacture, e.g., interferometric modulators of the general type illustrated in FIGS. 1 and 6, in addition to other blocks not shown in FIG. 7. With reference to FIGS. 1, 6 and 7, the process 80 begins at block 82 with the formation of the optical stack 16 over the substrate 20. FIG. 8A illustrates such an optical stack 16 formed over the substrate 20. The substrate 20 may be a transparent substrate such as glass or plastic, it may be flexible or relatively stiff and unbending, and may have been subjected to prior preparation processes, e.g., cleaning, to facilitate efficient formation of the optical stack 16. As discussed above, the optical stack 16 can be electrically conductive, partially transparent and partially reflective and may be fabricated, for example, by depositing one or more layers having the desired properties onto the transparent substrate 20. In FIG. 8A, the optical stack 16 includes a multilayer structure having sub-layers 16a and 16b, although more or fewer sub-layers may be included in some other implementations. In some implementations, one of the sub-layers 16a, 16b can be configured with both optically absorptive and conductive properties, such as the combined conductor/absorber sub-layer 16a. Additionally, one or more of the sub-layers 16a, 16b can be patterned into parallel strips, and may form row electrodes in a display device. Such patterning can be performed by a masking and etching process or another suitable process known in the art. In some implementations, one of the sub-layers 16a, 16b can be an insulating or dielectric layer, such as sub-layer 16b that is deposited over one or more metal layers (e.g., one or more reflective and/or conductive layers). In addition, the optical stack 16 can be patterned into individual and parallel strips that form the rows of the display.

The process 80 continues at block 84 with the formation of a sacrificial layer 25 over the optical stack 16. The sacrificial layer 25 is later removed (e.g., at block 90) to form the cavity 19 and thus the sacrificial layer 25 is not shown in the resulting interferometric modulators 12 illustrated in FIG. 1. FIG. 8B illustrates a partially fabricated device including a sacrificial layer 25 formed over the optical stack 16. The formation of the sacrificial layer 25 over the optical stack 16 may include deposition of a xenon difluoride (XeF₂)-etchable material such as molybdenum (Mo) or amorphous silicon (a-Si), in a thickness selected to provide, after subsequent removal, a gap or cavity 19 (see also FIGS. 1 and 8E) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 80 continues at block 86 with the formation of a support structure e.g., a post 18 as illustrated in FIGS. 1, 6 and 8C. The formation of the post 18 may include patterning the sacrificial layer 25 to form a support structure aperture, then depositing a material (e.g., a polymer or an inorganic material, e.g., silicon oxide) into the aperture to form the post 18, using a deposition method such as PVD, PECVD, thermal CVD, or spin-coating. In some implementations, the support structure aperture formed in the sacrificial layer can extend through both the sacrificial layer 25 and the optical stack 16 to the underlying substrate 20, so that the lower end of the post 18 contacts the substrate 20 as illustrated in FIG. 6A. Alternatively, as depicted in FIG. 8C, the aperture formed in the sacrificial layer 25 can extend through the sacrificial layer 25, but not through the optical stack 16. For example, FIG. 8E illustrates the lower ends of the support posts 18 in contact with an upper surface of the optical stack 16. The post 18, or other support structures, may be formed by depositing a layer of support structure material over the sacrificial layer 25 and patterning portions of the support structure material located away from apertures in the sacrificial layer 25. The support structures may be located within the apertures, as illustrated in FIG. 8C, but also can, at least partially, extend over a portion of the sacrificial layer 25. As noted above, the patterning of the sacrificial layer 25 and/or the support posts 18 can be performed by a patterning and etching process, but also may be performed by alternative etching methods.

The process 80 continues at block 88 with the formation of a movable reflective layer or membrane such as the movable reflective layer 14 illustrated in FIGS. 1, 6 and 8D. The movable reflective layer 14 may be formed by employing one or more deposition steps, e.g., reflective layer (e.g., aluminum, aluminum alloy) deposition, along with one or more patterning, masking, and/or etching steps. The movable reflective layer 14 can be electrically conductive, and referred to as an electrically conductive layer. In some implementations, the movable reflective layer 14 may include a plurality of sub-layers 14a, 14b, 14c as shown in FIG. 8D. In some implementations, one or more of the sub-layers, such as sub-layers 14a, 14c, may include highly reflective sub-layers selected for their optical properties, and another sub-layer 14b may include a mechanical sub-layer selected for its mechanical properties. Since the sacrificial layer 25 is still present in the partially fabricated interferometric modulator formed at block 88, the movable reflective layer 14 is typically not movable at this stage. A partially fabricated IMOD that contains a sacrificial layer 25 may also be referred to herein as an “unreleased” IMOD. As described above in connection with FIG. 1, the movable reflective layer 14 can be patterned into individual and parallel strips that form the columns of the display.

The process 80 continues at block 90 with the formation of a cavity, e.g., cavity 19 as illustrated in FIGS. 1, 6 and 8E. The cavity 19 may be formed by exposing the sacrificial material 25 (deposited at block 84) to an etchant. For example, an etchable sacrificial material such as Mo or amorphous Si may be removed by dry chemical etching, e.g., by exposing the sacrificial layer 25 to a gaseous or vaporous etchant, such as vapors derived from solid XeF₂ for a period of time that is effective to remove the desired amount of material, typically selectively removed relative to the structures surrounding the cavity 19. Other etching methods, e.g. wet etching and/or plasma etching, also may be used. Since the sacrificial layer 25 is removed during block 90, the movable reflective layer 14 is typically movable after this stage. After removal of the sacrificial material 25, the resulting fully or partially fabricated IMOD may be referred to herein as a “released” IMOD.

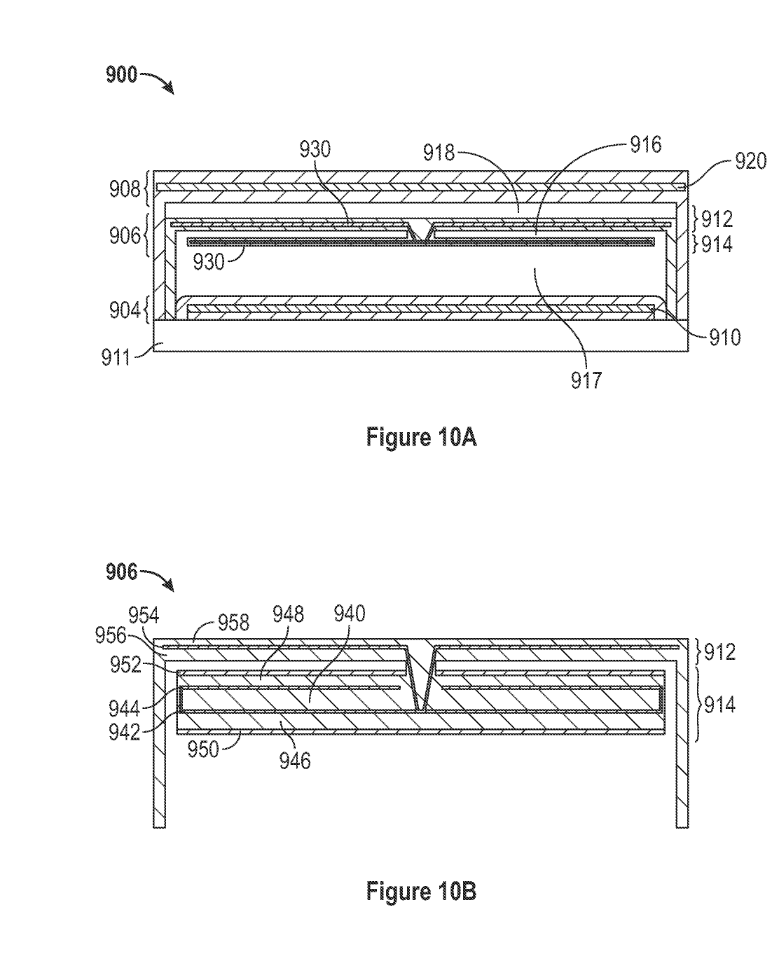

FIGS. 9A and 9B show examples of a cross-section of an analog IMOD (AIMOD). With reference to FIG. 9A, the AIMOD 900 includes a substrate 911 and an optical stack 904 disposed over the substrate 911. The AIMOD includes a first electrode 910 and a second electrode 920 (as illustrated, the first electrode 910 is a lower electrode, and second electrode 920 is an upper electrode). The second electrode 920 can be disposed within a stationary element 908. For example, in some implementations the stationary element 908 can include the second electrode 920 embedded within a dielectric material. The AIMOD 900 also includes a movable element 906 disposed between the first electrode 910 and the second electrode 920. The movable element 906 can include a deformable layer 912 and a reflector 914. As illustrated, the reflector 914 is separated from the deformable layer 912 by a gap 916. The reflector 914 is coupled to the deformable layer 912 at a substantially center portion. In this configuration, the optical properties of the movable element 906 can be decoupled from its mechanical properties because the optical properties are mostly attributable to the reflector 914 while the mechanical properties are mostly attributable to the deformable layer 912. During actuation, the movable element 906 can move in response to applied voltage across the first and second electrodes 910 and 920. The third electrode (not shown) embedded within the movable element 906 can be provided with a charge and accordingly, can move towards either of the first or second electrodes 910 and 920, depending on their respective charges. With this movement, the height of the cavity 917 between the reflector 914 and the optical stack 904 is varied. Due to the separation of the reflector 914 from the deformable layer 912, bending of the deformable layer 912 does not translate into bending of the reflector 914. Rather, the reflector 914 can be moved vertically relative to the first and second electrodes 910 and 920, while remaining substantially planar. In some implementations, the reflector 914 remains substantially parallel to the optical stack 904 during actuation. Additionally, since the reflector 914 generally does not bend during actuation of the AIMOD 900, the reflector 914 does not suffer distortion from bending in the peripheral regions. Accordingly, the optically active area of the reflector 914 can be increased, resulting in a higher fill factor.

In some implementations, the optical stack 904 includes an absorbing layer, and/or a plurality of other layers, and can be configured similar to the optical stack 16 illustrated in FIGS. 6A-6E. In some implementations, and in the example illustrated in FIG. 9A, the optical stack 904 includes the first electrode 910 which is further configured as an absorbing layer. In such a configuration, the absorbing layer, which is also the first electrode 910, can be an approximately 6 nm thick layer of material that includes MoCr. In some implementations, the layer of material including MoCr can have a thickness ranging from approximately 2 nm to 10 nm.

Still referring to FIG. 9A, the movable element 906 can be charged. For example, in some implementations the movable element 906 can include a third electrode embedded therein (not shown). The movable element 906 is configured to, once charged, move toward either the first electrode 910 or the second electrode 920 when a voltage is applied between the first and second electrodes 910 and 920. In this manner, the movable element 906 can be driven through a range of positions between the two electrodes 910 and 920, including above and below a relaxed (unactuated) state. For example, FIG. 9B illustrates that the reflector 914 of the movable element 906 can be moved (or actuated) to various positions 930, 932 and 934 between the first electrode 910 and the second electrode 920.

The AIMOD 900 can be configured to selectively reflect certain wavelengths of light depending on the configuration of the AIMOD 900. The distance between the optical stack 904, which includes an absorbing layer, and the reflector 914 changes the reflective properties of the AIMOD 900. Any particular wavelength is maximally reflected from the AIMOD 900 when the distance between the reflector 914 and the absorbing layer of the optical stack 904 is such that the absorbing layer is located at the minimum light intensity of standing waves resulting from interference between incident light and light reflected from the reflector 914. For example, as illustrated, the AIMOD 900 is designed to be viewed from the substrate 911 side of the AIMOD and through the substrate 911. In other words, light enters the AIMOD 900 through the substrate 911. Depending on the position of the reflector 914, different wavelengths of light are reflected back through the substrate 911, which gives the appearance of different colors. These different colors are also known as native colors.

A position of a movable element 906 of a display element (e.g., an AIMOD) at a location such that it reflects a certain wavelength or wavelengths can be referred to a display state. For example, when the reflector 914 is in position 930, red light are reflected in greater proportion than light having other wavelengths, which are absorbed in greater proportion than red light. Accordingly, the AIMOD 900 appears red and is said to be in a red display state, or simply a red state. Similarly, the AIMOD 900 is in a green display state (or green state) when the reflector 914 moves to position 932, where green light are reflected in greater proportion than light having other wavelengths, which are absorbed in greater proportion than green light. When the reflector 914 moves to position 934, the AIMOD 900 is in a blue display state (or blue state) and blue light are reflected in greater proportion than light having other wavelengths, which are absorbed in greater proportion than blue light. Additionally, the reflector 914 may be moved to other positions to achieve a white display state (or white state), in which light having a broad range of wavelengths in the visible spectrum are substantially reflected such that the AIMOD 900 appears “white.” The mirror position of the reflector 914 that generates a white state is typically a closed position with no air gap between the reflector 914 and the optical stack 904. The dielectric film thickness is designed to generate white at closed state. A dark state will be typically be produced with a 1000-1200 Å air gap between the reflector 914 and the optical stack 904. It should be noted that one having ordinary skill in the art will readily recognize that the AIMOD 900 can take on different states and selectively reflect other wavelengths of light based on the position of the reflector 914, and also based on materials that are used in construction of the AIMOD 900, particularly various layers in the optical stack 904.

The AIMOD 900 in FIGS. 9A and 9B has two structural cavities, a first cavity 916 between the reflector 914 and the optical stack 904, and a second cavity 918 between the deformable layer 912 and the second electrode 920. However, because the reflector 914 is reflective and not transmissive, light does not propagate through the reflector 914 into the second cavity 918. In addition, the color and/or intensity of light reflected by the AIMOD 900 is determined by the distance between the reflector 914 and the absorbing layer of the optical stack 904. Accordingly, the AIMOD 900 illustrated in FIGS. 9A and 9B has one interferometric (absorbing) cavity 916. Note that incident light, which entered the first cavity 916, does not enter the second cavity 918.

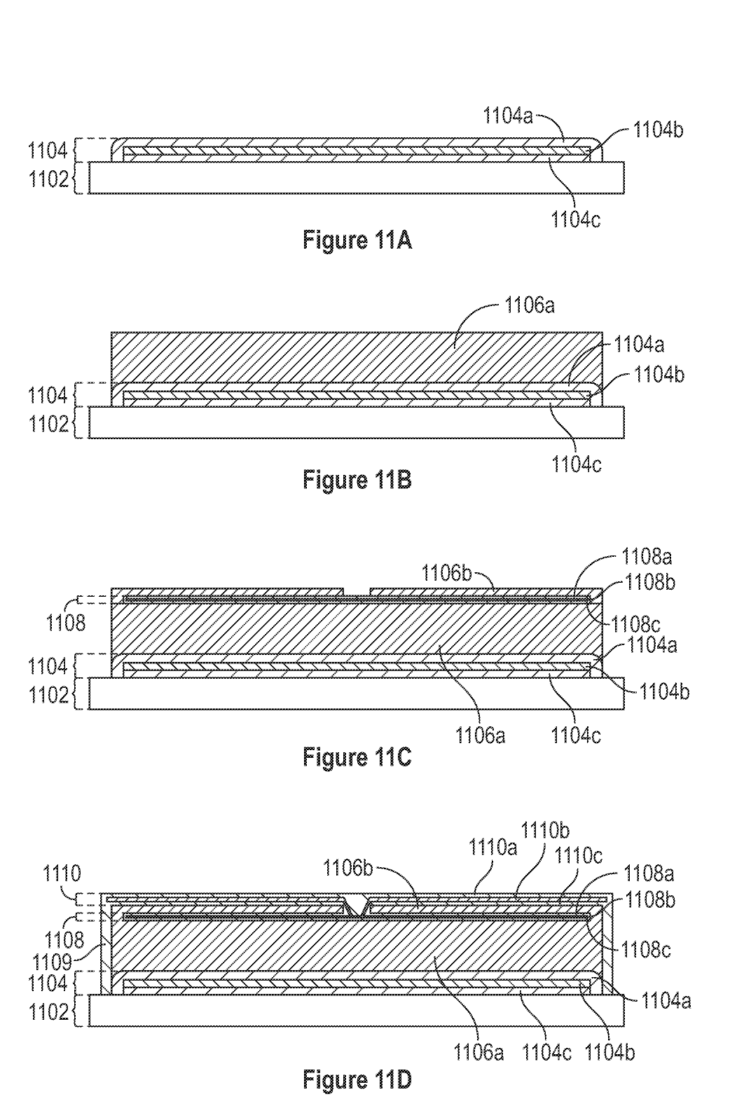

FIG. 10A shows another example of a cross-section of an AIMOD. The AIMOD 900 is similar to that described above with respect to FIGS. 9A and 9B. With reference to FIG. 10A, the AIMOD 900 includes a substrate 911 and an optical stack 904 disposed over the substrate 911. A first electrode 910 is part of the optical stack 904, and the second electrode 920 can be disposed within the stationary element 908. The movable element 906 includes a deformable layer 912 and a reflector 914. As noted above, the reflector 914 is separated from the deformable layer 912 by a gap 916, while being coupled to the deformable layer 912 at a substantially center portion.

Still referring to FIG. 10A, the movable element 906 can include a third electrode 930. The third electrode 930 can be charged so that, once charged, the movable element 906 can move toward either the first electrode 910 or the second electrode 920 when a voltage is applied between the first and second electrodes 910, 920. In this manner, the movable element 906 can be driven through a range of positions between the first and second electrodes 920 and 910, as illustrated in FIG. 9B. With reference to FIG. 10A, the third electrode 930 is disposed within both the deformable layer 912 and the reflector 914. In other implementations, the third electrode 930 can be confined to the deformable layer, and may not extend to the reflector 914. In other implementations, the third electrode 930 may be positioned within the reflector 914, but not within the deformable layer 912.

FIG. 10B shows an enlarged detail view of the movable element 906 shown in FIG. 10A. As noted above, the movable element 906 includes a deformable layer 912 and a reflector 914. The third electrode 930 extends through both the deformable layer 912 and the reflector 914. As illustrated in FIG. 10B, reflector 914 can include a plurality of sub-layers. For example, a first dielectric layer 940 is positioned near the center of the reflector 914. In some implementations, the first dielectric layer 940 can have a thickness of approximately 5000 Å, providing it with substantial rigidity. The dielectric layer 940 can be made of nitrous oxide, silicon dioxide, silicon nitride, or other suitable dielectric material.

A first metal layer 942 is arranged beneath the first dielectric layer 940, and faces the optical stack (not shown). A second metal layer 944 is arranged above the first dielectric layer 940. Either or both of the first and second metal layers 942 and 944 can include aluminum, copper, or other conductive material. In some implementations, the first and second metal layers 942 and 944 are electrically connected to one another and together are part of the third electrode 930. In other implementations, one or neither of the first and second metal layers 942 and 944 can be part of the third electrode 930. In implementations in which one or both of the first and second metal layers 942 and 944 are not part of the third electrode 930, the metal layers can serve to provide desired mechanical characteristics to the reflector 914. Either or both of the first and second metal layers 942 and 944 can have a thickness of approximately 300 A. In some implementations, the materials and thicknesses of the first and second metal layers 942 and 944 can be substantially identical. Such symmetrical construction can provide increased rigidity to the reflector 914, and can also reduce warpage or stress caused by a mis-match of the coefficients of thermal expansion. In some implementations, the materials and or thicknesses of the first and second metal layers 942 and 944 can vary.

With continued reference to FIG. 10B, a second dielectric layer 946 can be disposed beneath the first metal layer 942, and a third dielectric layer 948 can be disposed over the second metal layer 944. Either or both of the second and third dielectric layers 946 and 948 can include nitrous oxide, silicon dioxide, silicon nitride, or other suitable dielectric material. In some implementations, either or both of the second and third dielectric layers 946 and 948 can have a thickness of approximately 650 Å. In some implementations, the materials and thicknesses of the second and third dielectric layers 946 and 948 can be substantially identical. In some implementations, the materials and/or thicknesses of the second and third dielectric layers 946 and 948 can vary. In the illustrated configuration, neither the first nor second metal layers 940 and 942 are exposed to the environment. Accordingly, second and third dielectric layers 946 and 948 serve to protect the first and second metal layers 940 and 942 from environmental damage and corrosion. Additionally, these second and third dielectric layers 946 and 948 can be dimensioned so as to contribute to the overall stiffness of the reflector 914.

A first optical layer 950 can be disposed beneath the third dielectric layer 946, and a second optical layer 952 can be disposed above the fourth dielectric layer 948. The first optical layer 950 can face the optical stack 904. In some implementations, either or both of the first and second optical layers 950 and 952 can include titanium dioxide. The first and second optical layers 950 and 952 can be configured to have a high refractive index relative to the adjacent dielectric layers. For instance, the first and second optical layers 950 and 952 that are made of titanium dioxide can have a refractive index of approximately 3. These high refractive index optical layers 950 and 952 can improve the reflected color quality from the AIMOD. In some implementations, either or both of the first and second optical layers 950 and 952 and can be configured to be substantially reflective. In some implementations, the first and second optical layers 950 and 952 can have substantially identical materials and thicknesses. In other implementations, the materials and/or thicknesses of the first and second optical layers 950 and 952 can differ.

Still referring to FIG. 10B, the deformable layer 912 can also include a plurality of sub-layers. As illustrated, the deformable layer 912 can include a third metal layer 954. In some implementations, the third metal layer 954 can be made of aluminum copper or other conductive material. In some implementations, the third metal layer 954 can be electrically connected to either or both of the first and second metal layers 942 and 944. In the illustrated implementation, each of the first, second, and third metal layers 942, 944 and 954 are electrically connected and together form the third electrode 930. In other implementations, any one of the first, second, or third metal layers 942, 944 and 954 may individually serve as the third electrode 930. In other implementations, two of the first, second, or third metal layers 942, 944 and 954 may be electrically connected and serve as the third electrode 930, without providing electrical connection to the remaining one of the first, second, or third metal layers 942, 944 and 954.

The deformable layer 912 can further include a fourth dielectric layer 956 disposed beneath the third metal layer 954, and a fifth dielectric layer 958 disposed over the third metal layer 954. Either or both of the fourth and fifth dielectric layers 956 and 958 can include nitrous oxide, silicon dioxide, silicon nitride, or other suitable dielectric material. In some implementations, either or both of the fourth and fifth dielectric layers 956 and 958 can have thicknesses of between about 500 and 5000 Å. Such relatively thick dielectric layers can provide sufficient structural support, while retaining the flexibility required for the deformable layer to bend in response to an electric field. In some implementations, the materials and thicknesses of the fourth and fifth dielectric layers 956 and 958 can be substantially identical. In some implementations, the materials and/or thicknesses of the second and third dielectric layers 956 and 958 can vary.

Because the deformable layer 912 is separated from the reflector 914 by a gap 916 across most of their respective lengths, the mechanical properties of the deformable layer 912 can be adjusted separately from the optical properties of the reflector 914. Accordingly, the materials and thicknesses for the respective sub-layers of the deformable layer 912 may be selected to achieve desired mechanical characteristics, while the materials and thicknesses for the respective sub-layers of the reflector 914 can be selected to achieve desired optical characteristics. This allows for wide design freedom to vary the properties of the deformable layer 912 and the reflector 914 as desired, depending on the application.

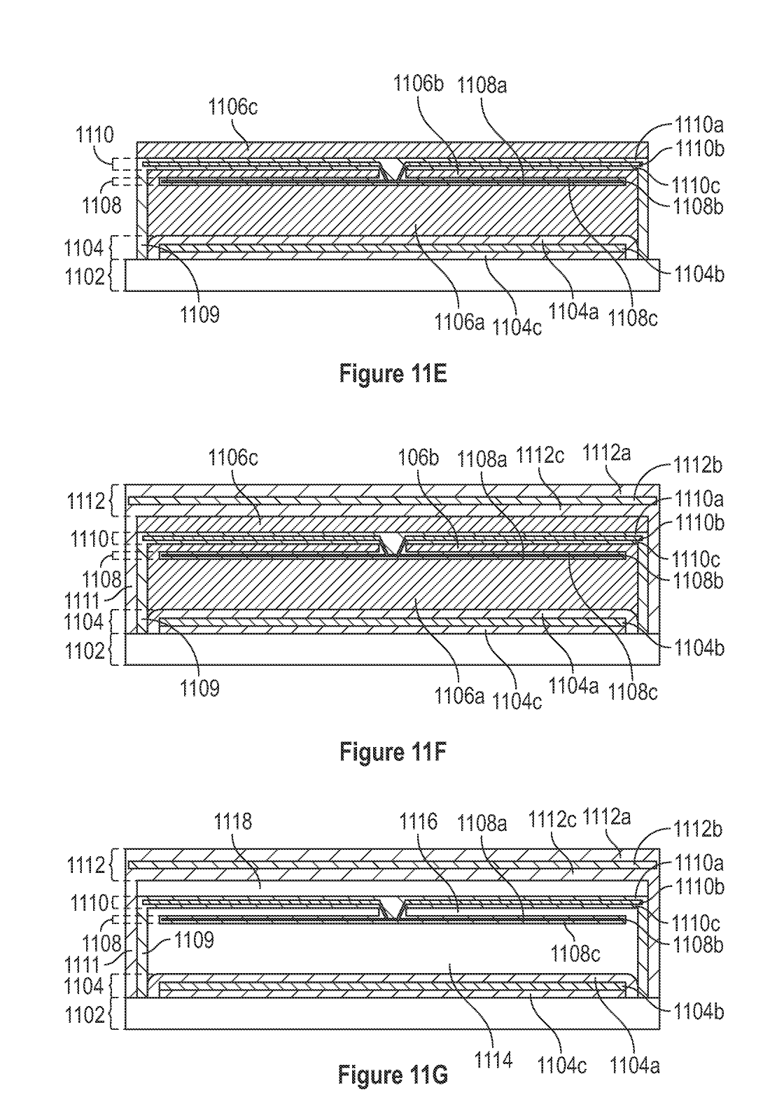

FIGS. 11A-11G show examples of cross-sectional schematic illustrations of various stages in one implementation of a method of making an AIMOD. First, as illustrated in FIG. 11A, an optical stack 1104 is formed over a substrate 1102. The substrate 1102 may be a transparent substrate such as glass or plastic, it may be flexible or relatively stiff and unbending, and may have been subjected to prior preparation processes (for example, cleaning) to facilitate efficient formation of the optical stack 1104. As discussed above, the optical stack 1104 can be electrically conductive, partially transparent and partially reflective and may be fabricated, for example, by depositing one or more layers having the desired properties onto the transparent substrate 1102. In FIG. 11A, the optical stack 1104 includes a multilayer structure having sub-layers 1104a, 1104b and 1104c, although more or fewer sub-layers may be included in some other implementations. In some implementations, one of the sub-layers 1104a, 1104b and 1104c can be configured with both optically absorptive and conductive properties, such as the combined electrode/absorber sub-layer 1104b. Additionally, one or more of the sub-layers 1104a, 1104b and 1104c can be patterned into parallel strips, and may form row electrodes in a display device. Such patterning can be performed by a masking and etching process or another suitable process known in the art. In some implementations, one or more of the sub-layers 1104a, 1104b and 1104c can be an insulating or dielectric layer, such as sub-layers 1104a that is deposited over one or more metal layers (for example, one or more reflective and/or conductive layers). In addition, the optical stack 1104 can be patterned into individual and parallel strips that form the rows of the display.

Next, a sacrificial layer 1106a is formed over the optical stack 1104. The sacrificial layer 1106a is later removed (see FIG. 11G) to form the cavity 1114 and thus the sacrificial layer 1106a is not shown in the resulting AIMOD illustrated in FIG. 11G. FIG. 11B illustrates a partially fabricated device including the sacrificial layer 1106a formed over the optical stack 1104. The formation of the sacrificial layer 1106a over the optical stack 1104 may include deposition of a xenon difluoride (XeF₂)-etchable material such as molybdenum (Mo) or amorphous silicon (a-Si), in a thickness selected to provide, after subsequent removal, a gap or cavity 1114 (see also FIG. 11G) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

Next, the reflector 1108 is formed, as illustrated in FIG. 11C. The reflector 1108 may be formed by employing one or more deposition steps (or processes), for example, reflective layer deposition, along with one or more patterning, masking, and/or etching steps. In some implementations, the reflective layer can include aluminum (Al) or an aluminum alloy. The reflector 1108 can be electrically conductive, and can include an electrically conductive layer. In some implementations, the reflector 1108 may include a plurality of sub-layers 110a, 1108b and 1108c as shown in FIG. 11C. In some implementations, one or more of the sub-layers 110a, 1108b and 1108c may include highly reflective sub-layers selected for their optical properties, and another sub-layer may include a mechanical sub-layer selected for its mechanical properties. In some implementations, one or more of the sub-layers 110a, 1108b and 1108c may be electrically conductive, and can form part of an electrode.

In some implementations, formation of the reflector 1108 can include deposition of a first layer including titanium dioxide as a highly reflective material (for example, 950 in FIG. 10B). In some implementations, the first reflective layer can be deposited at a thickness of approximately 285 Å. Next, a layer of dielectric material such as silicon nitride or silicon dioxide (for example, 946 in FIG. 10B) can be formed over the first reflective layer. In some implementations, the dielectric layer can be deposited at a thickness of approximately 650 Å. Next a conductive layer, such as aluminum copper (AlCu), may be deposited (for example, first metal layer 942 in FIG. 10B). In some implementations, the conductive layer can be deposited with a thickness of approximately 300 Å. This can be followed by a relatively thick layer of dielectric material (for example, first dielectric layer 940 in FIG. 10B). In some implementations, the relatively thick layer may be approximately 5000 Å thick. A symmetrical set of layers can be formed over the relatively thick dielectric layer. For example, another conductive layer (for example, second metal layer 944 in FIG. 10B) may be formed over the relatively thick dielectric layer, followed by another layer of dielectric material (for example, third dielectric layer 948 in FIG. 10B). Finally, another layer of reflective material (for example, second optical layer 952 in FIG. 10B) may be formed over the layer of dielectric material. In some implementations, the materials and thicknesses of these layers may be selected so as to create a substantially symmetrical stack in the reflector 1108. In other implementations, one or more of the materials and/or thicknesses of the layers may be varied from a symmetrical arrangement.

With continued reference to FIG. 11C, the sacrificial layer 1106a is still present in the partially fabricated AIMOD, so the reflector 1108 is typically not movable at this stage. A partially fabricated AIMOD that contains a sacrificial layer 1106a may also be referred to herein as an “unreleased” AIMOD. A second sacrificial layer 1106b can be formed over the reflector 1108, as illustrated in FIG. 11C. Formation of the sacrificial layer 1106b can be carried out as described above with respect to the first sacrificial layer 1106a. For example, the formation of the sacrificial layer 1106b may include deposition of a xenon difluoride (XeF₂)-etchable material such as molybdenum (Mo) or amorphous silicon (a-Si), in a thickness selected to provide, after subsequent removal, a gap or cavity 1116 (see also FIG. 11G) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating. A portion of the second sacrificial layer 1106b may be removed by photolithography followed by etching. For example, a dry chemical etch may be used to define the opening in the second sacrificial layer 1106b.

Next, as illustrated in FIG. 11D, the deformable layer 1110 can be formed over the second sacrificial layer 1106b, and can be connected to the reflector 1108. The deformable layer 1110 may be formed by employing one or more deposition steps, e.g., a dielectric layer, followed by a conductive layer (e.g., aluminum copper) deposition, along with one or more patterning, masking, and/or etching steps. The deformable layer 1110 include an electrically conductive sub-layer. In some implementations, the reflector 1110 may include a plurality of sub-layers 1110a, 1110b and 1110c as shown in FIG. 11D. In some implementations, one or more of the sub-layers may include conductive sub-layers selected for their electrical properties, and one or more additional sub-layers may include mechanical sub-layers selected for their mechanical properties.

In some implementations, formation of the deformable element 1110 can include first depositing a first dielectric layer 1110c over the sacrificial layer 1106b (and over the exposed portion of the reflector 1108). In some implementations, the dielectric layer 1110c can include silicon dioxide and/or silicon nitride, and can be deposited at a thickness of between about 500 and 5000 Å. Next, the newly deposited dielectric layer 1110c may be etched in a region aligned with the previously exposed portion of the reflector 1108. This region can be etched to remove both the dielectric layer 1110c of the deformable layer 1110, and the dielectric layer 1108a of the reflector, leaving exposed the conductive layer 1108b of the reflector 1108. Next, a conductive sub-layer 1110b can be deposited. In some implementations, the conductive sub-layer 1110b can include aluminum copper deposited at a thickness of approximately 300 Å. As the conductive sub-layer 1108b of the reflector 1108 is exposed prior to deposition, the two conductive sub-layers 1108b and 1110c can be in direct contact, and therefore electrically connected. In some implementations, these sub-layers 1108b and 1110c together can form part of the third electrode (for example, 930 in FIGS. 9A and 9B, and FIGS. 10A and 10B). Next, another dielectric layer 1110a can be deposited over the conductive sub-layer 1110b. In some implementations, the dielectric sub-layer 1110a can include silicon dioxide and/or silicon nitride, and can be deposited at a thickness of between about 500 and 5000 Å.

Along with formation of the deformable element 1110, support posts 1109 can be formed. The formation of the posts 1109 may include patterning the first and second sacrificial layers 106a, 106b to form a support structure aperture, then depositing a material (for example, a polymer or an inorganic material, e.g., silicon oxide) into the aperture to form the post 1109, using a deposition method such as PVD, PECVD, thermal CVD, or spin-coating. In some implementations, the support structure aperture formed in the sacrificial layer can extend through both the sacrificial layers 1106a and 1106b and the optical stack 1104 to the underlying substrate 1102, so that the lower end of the post 1109 contacts the substrate 1102 as illustrated in FIG. 11C. Alternatively, the aperture formed in the sacrificial layers 1106a and 1106b can extend through the sacrificial layers 1106a and 1106b, but not through the optical stack 1104. As noted above, the patterning of the sacrificial layers 1106a and 1106b and/or the support posts 1109 can be performed by a patterning and etching process, but also may be performed by alternative etching methods.

Next, as illustrated in FIG. 11E, a third sacrificial layer 1106c can be deposited over the deformable element 1110. This sacrificial layer 1106c is later removed (see FIG. 11G) to form the cavity 1118 and thus the sacrificial layer 1106c is not shown in the resulting AIMOD illustrated in FIG. 11G. FIG. 11D illustrates a partially fabricated device including a sacrificial layer 1106a formed over the deformable element 1110. The formation of the sacrificial layer 1106c over the deformable element 1110 may include deposition of a xenon difluoride (XeF₂)-etchable material such as molybdenum (Mo) or amorphous silicon (a-Si), in a thickness selected to provide, after subsequent removal, a gap or cavity 1118 (see also FIG. 11G) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

With reference to FIG. 11F, a stationary element 1112 can be formed over the third sacrificial layer 1106c. The stationary element 1112 can include within it a conductive sub-layer 1112b. In the illustrated implementation, the conductive sub-layer 1112b is surrounded by two dielectric sub-layers 1112a and 1112c. In some implementations, each of the dielectric sub-layers 1112a and 1112c can include silicon nitride and/or silicon dioxide, and can have thicknesses ranging from approximately 1 to 3 microns. In some implementations, the conductive sub-layer 1112b can form an electrode, and as described above can include aluminum copper deposited at a thickness of approximately 300 Å.

Along with formation of the stationary element 1112, additional support posts 1111 can be formed. The formation of the posts 1111 may include patterning the first, second, and third sacrificial layers 1106a, 1106b and 1106c to form a support structure aperture, then depositing a material (e.g., a polymer or an inorganic material, e.g., silicon oxide) into the aperture to form the post 1111, using a deposition method such as PVD, PECVD, thermal CVD, or spin-coating. In some implementations, the support structure aperture formed in the sacrificial layer can extend through both the sacrificial layers 1106a, 1106b and 1106c and the optical stack 1104 to the underlying substrate 1102, so that the lower end of the post 1111 contacts the substrate 1102 as illustrated in FIG. 11F. Alternatively, the aperture formed in the sacrificial layers 1106a, 1106b and 1106c can extend through the sacrificial layers 1106a, 1106b and 1106c but not through the optical stack 1104. As noted above, the patterning of the sacrificial layers 1106a, 1106b and 1106c and/or the support posts 1111 can be performed by a patterning and etching process, but also may be performed by alternative etching methods.

As illustrated in FIG. 11G, the cavities 1114, 1116 and 1118 may be formed by exposing the sacrificial layers 1106a, 1106b and 1106c to an etchant. For example, an etchable sacrificial material such as Mo or amorphous Si may be removed by dry chemical etching, e.g., by exposing the sacrificial layers 1106a, 1106b and 1106c to a gaseous or vaporous etchant, such as vapors derived from solid XeF₂ for a period of time that is effective to remove the desired amount of material, typically selectively removed relative to the structures surrounding the cavities 1114, 1116 and 1118. Other etching methods, e.g. wet etching and/or plasma etching, also may be used. Once the sacrificial layers 1106a, 1106b and 1106c are removed, the deformable element 1110 and reflector 1108 are typically movable. After removal of the sacrificial layers 1106a, 1106b and 1106c, the resulting fully or partially fabricated AIMOD may be referred to herein as a “released” AIMOD.

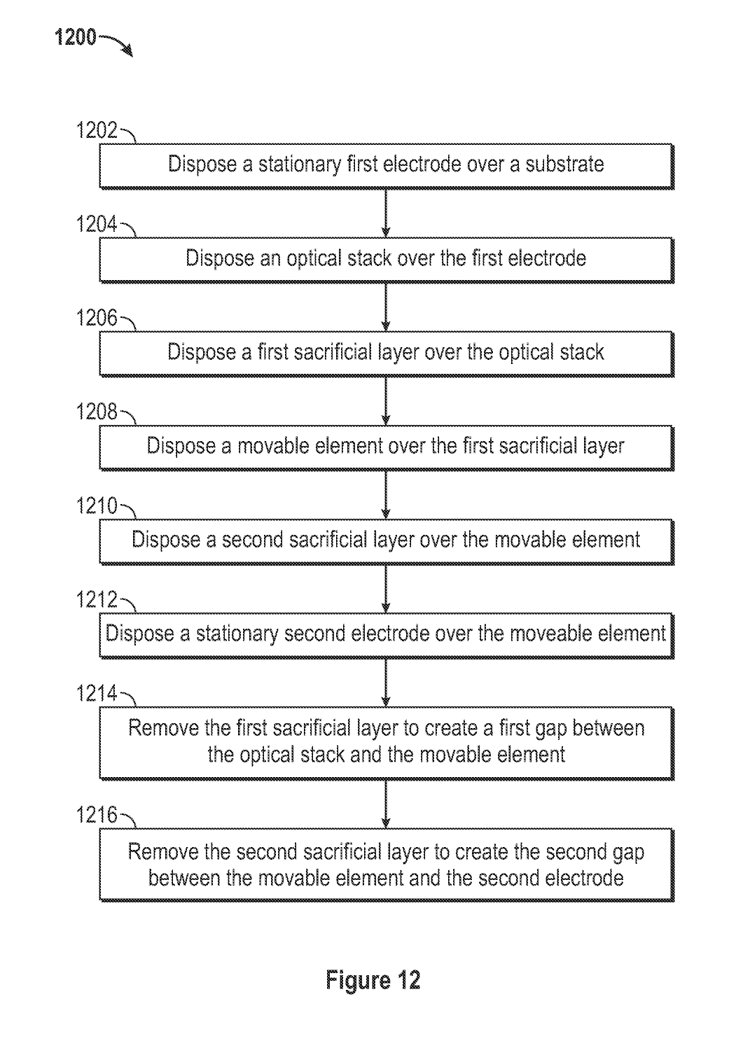

FIG. 12 shows an example of a flow diagram illustrating one implementation of a method of manufacturing an AIMOD. In block 1202 process 1200 disposes a stationary first electrode over a substrate. In some implementations, the substrate may be made of glass or clear plastic. The process 1200 continues at block 1204 with disposing an optical stack over the first electrode. In some implementations, the optical stack can include an absorbing layer, such as MoCr or Vanadium, and the absorbing layer can have a thickness of between about 2 and 10 nm. In some implementations, one or more dielectric layers may be deposited onto the substrate prior to the formation of the absorbing layer. In some implementations, another dielectric layer may be formed over the absorbing layer after it is formed on the substrate. In such a configuration, the optical stack includes two or more dielectric layers separated by the absorbing layer. The process 1200 continues at block 1206 with disposing a first sacrificial layer over the optical stack. Formation of the first sacrificial layer over the optical stack may include deposition of a xenon difluoride (XeF₂)-etchable material such as molybdenum (Mo) or amorphous silicon (a-Si), in a thickness selected to provide, after subsequent removal, a first gap (block 1214) having a desired design size. Deposition of the sacrificial material may be carried out using deposition techniques such as physical vapor deposition (PVD, e.g., sputtering), plasma-enhanced chemical vapor deposition (PECVD), thermal chemical vapor deposition (thermal CVD), or spin-coating.

The process 1200 continues at block 1208 with disposing a movable element over the first sacrificial layer. In some implementations, the movable element includes a deformable layer and a reflector, and a third electrode. The movable element can be configured to move in response to at least one of a first electric field between the first and third electrodes, and a second electric field between the second and third electrodes. The movable element can be configured to move to at least three different positions relative to the optical stack, each position corresponding to a different color reflected from the AIMOD. The reflector can include a first metal layer facing the optical stack, and a first dielectric layer disposed over the first metal layer. The deformable layer can be disposed over the reflector. A portion of the deformable layer can be coupled to the reflector, and a portion of the deformable layer can be spaced apart from a portion of the reflector by a gap.

The process 1200 continues in block 1210 with disposing a second sacrificial layer over the movable element. with disposing a stationary second electrode over the optical stack and spaced apart from the optical stack by a first gap. Similar with the first sacrificial layer, formation of the second sacrificial layer over the optical stack may include deposition of molybdenum (Mo) or amorphous silicon (a-Si), in a thickness selected to provide, after subsequent removal, a second gap (block 1216) having a desired design size. Deposition of the sacrificial material may be carried out using deposition techniques such as PVD, PECVD, thermal CVD, or spin-coating.

The process 1200 continues at block 1212 with disposing with disposing a stationary second electrode over the second sacrificial layer. In some implementations, the stationary second electrode can be disposed within a relatively thick dielectric layer, which can be suspended over the optical stack by a plurality of support posts. The process 1200 continues with removal of the first sacrificial layer to create a first gap between the optical stack and the movable element. In block 1216, the second sacrificial layer is removed to create a second gap between the movable element and the second electrode. The sacrificial material may be removed by exposing it to an etchant. For example, an etchable sacrificial material such as Mo or amorphous Si may be removed by dry chemical etching, e.g., by exposing the sacrificial layer to a gaseous or vaporous etchant, such as vapors derived from solid XeF₂ for a period of time that is effective to remove the desired amount of material, typically selectively removed relative to the structures surrounding the gaps. Other etching methods, e.g. wet etching and/or plasma etching, also may be used.

In some implementations, a second dielectric layer can be disposed over the first metal layer, and a second metal layer can be disposed over the second dielectric layer. In some implementations, the first and second metal layers can be electrically connected to form part of the third electrode. In some implementations, the first metal layer can have a thickness of at least about 300 Å. In some implementations, the first dielectric layer can have a thickness of at least about 5000 Å.

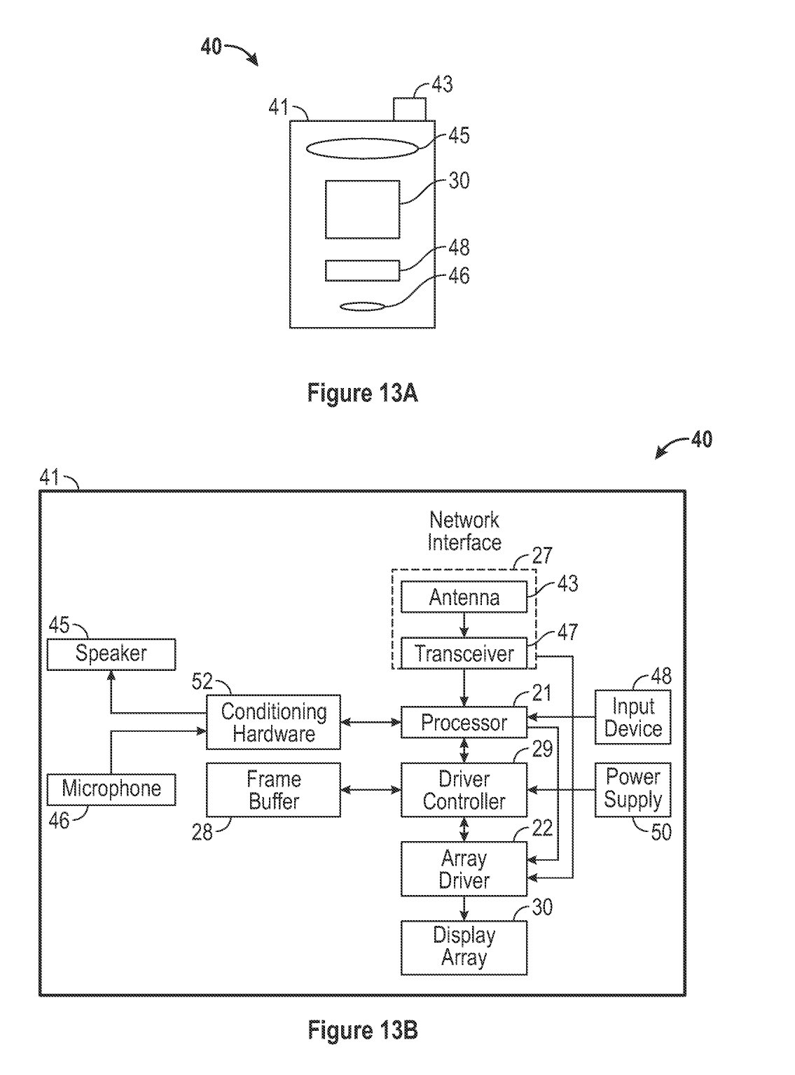

FIGS. 13A and 13B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an IMOD or AIMOD display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (for example, filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3G or 4G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint. The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD or AIMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. An analog interferometric modulator (AIMOD) comprising:
a stationary first electrode disposed over a substrate;
an optical stack disposed over the first electrode;
a stationary second electrode disposed over the optical stack and spaced apart from the optical stack by a first gap; and
a movable element disposed between the optical stack and second electrode, the movable element having a third electrode and being configured to move in response to at least one of a first electric field between the first and third electrodes and a second electric field between the second and third electrodes to at least three different positions relative to the optical stack, each position corresponding to a different color reflected from the AIMOD, wherein the movable element further includes:
a reflector including a first metal layer disposed facing the optical stack, and a first dielectric layer disposed such that the first metal layer is between the first dielectric layer and the optical stack; and
a deformable layer coupled to a portion of the reflector, the deformable layer disposed such that the reflector is between the deformable layer and the optical stack, wherein a portion of the deformable layer is spaced apart from a portion of the reflector by a second gap.

2. The AIMOD of claim 1, wherein the first metal layer includes aluminum.

3. The AIMOD of claim 1, wherein the first metal layer has a thickness of at least about 300 A.

4. The AIMOD of claim 1, wherein the first dielectric layer includes nitrous oxide.

5. The AIMOD of claim 1, wherein the first dielectric layer includes silicon dioxide.

6. The AIMOD of claim 1, wherein the first dielectric layer has a thickness of at least about 5000 Å.

7. The AIMOD of claim 1, wherein the first metal layer has a reflective surface that is disposed substantially parallel to the optical stack.

8. The AIMOD of claim 1, wherein the first metal layer is disposed over a second dielectric layer.

9. The AIMOD of claim 1, wherein a second metal layer is disposed over the first dielectric layer.

10. The AIMOD of claim 9, wherein the first and second metal layers are electrically connected and form part of the third electrode.

11. The AIMOD of claim 9, wherein the reflector further includes:
a second dielectric layer disposed below the first metal layer;
a third dielectric layer disposed over the second metal layer;
a first optical layer disposed below the second dielectric layer; and
a second optical layer disposed above the third dielectric layer.

12. The AIMOD of claim 11, wherein the second and third dielectric layers each have a thickness of at least about 650 Å.

13. The AIMOD of claim 11, wherein the deformable layer includes:
a third metal layer;
a fourth dielectric layer disposed below the third metal layer; and
a fifth dielectric layer disposed above the third metal layer;
wherein the fourth and fifth dielectric layers each have a thickness of at least about 1000 Å.

14. The AIMOD of claim 13, wherein the third metal layer is electrically connected to the first and second metal layers.

15. A device including the AIMOD of claim 1, the device comprising:
a display that includes the AIMOD;
a processor that is configured to communicate with the display, the processor being configured to process image data; and
a memory device that is configured to communicate with the processor.

16. The device of claim 15, further comprising:
a driver circuit configured to send at least one signal to the display.

17. The device of claim 16, further comprising:
a controller configured to send at least a portion of the image data to the driver circuit.

18. The device of claim 15, further comprising:
an image source module configured to send the image data to the processor.

19. The device of claim 18, wherein the image source module includes at least one of a receiver, transceiver, and transmitter.

20. The device of claim 15, further comprising:
an input device configured to receive input data and to communicate the input data to the processor.

21. An analog interferometric modulator (AIMOD) comprising:
stationary first means for conducting electrostatic charge disposed over a substrate;
means for absorbing light disposed over the first conducting means;
stationary second means for conducting electrostatic charge disposed over the absorbing means and spaced apart from the absorbing means by a first gap;
a movable element disposed between the absorbing means and the second conducting means, the movable element having third means for conducting electrostatic charge and being configured to move in response to at least one of a first electric field between the first and third conducting means and a second electric field between the second and third conducting means to at least three different positions relative to the absorbing means, each position corresponding to a different color reflected from the AIMOD, wherein the movable element further includes:
means for reflecting light, the reflecting means including a first metal layer disposed facing the absorbing means, and a first dielectric layer disposed such that the first metal layer is between the first dielectric layer and the absorbing means; and
a deformable layer coupled to a portion of the reflecting means, the deformable layer disposed such that the reflecting means is between the deformable layer and the absorbing means, wherein a portion of the deformable layer is spaced apart from a portion of the reflecting means by a second gap.

22. The AIMOD of claim 21, wherein the first conducting means includes a first electrode, or wherein the absorbing means includes an optical stack, or wherein the second conducting means includes a second electrode, or wherein the third conducting means includes a third electrode, or wherein the reflecting means includes a reflector.

23. A method of manufacturing an analog interferometric modulator (AIMOD), the method comprising:
disposing a stationary first electrode over a substrate;
disposing an optical stack over the first electrode;
disposing a first sacrificial layer over the optical stack;
disposing a movable element over the first sacrificial layer,
disposing a second sacrificial layer over the movable element;
disposing a stationary second electrode over the second sacrificial layer;
removing the first sacrificial layer to create a first gap between the optical stack and the movable element; and
removing the second sacrificial layer to create a second gap between the movable element and the second stationary electrode,
the movable element having a third electrode and being configured to move in response to at least one of a first electric field between the first and third electrodes and a second electric field between the second and third electrodes to at least three different positions relative to the optical stack, each position corresponding to a different color reflected from the AIMOD;
wherein the movable structure further includes
a reflector including a first metal layer disposed facing the optical stack, and a first dielectric layer disposed such that the first metal layer is between the first dielectric layer and the optical stack; and
a deformable layer coupled to a portion of the reflector, the deformable layer disposed such that the reflector is between the deformable layer and the optical stack, wherein a portion of the deformable layer is spaced apart from a portion of the reflector by a second gap.

24. The method of claim 23, wherein a second dielectric layer is disposed over the first metal layer, and wherein a second metal layer is disposed over the second dielectric layer.

25. The method of claim 24, wherein the first and second metal layers are electrically connected and form part of the third electrode.

26. The method of claim 23, wherein the first metal layer has a thickness of at least about 300 Å.

27. The method of claim 23, wherein the first dielectric layer has a thickness of at least about 5000 Å.
